(19) United States
(12) Patent Application Publication
(10) Pub. No.: US 2005/0205994 A1
(43) Pub. Date: Sep. 22, 2005

(54) Signal transmitting device with vias and solder balls

(75) Inventor: Sheng-Yuan Lee, Xindian City (TW)

Correspondence Address: BRUCE H. TROXELL, SUITE 1404, 5205 LEESBURG PIKE, FALLS CHURCH, VA, 22041, US

(73) Assignee: Via Technologies, Inc.

(21) Appl. No.: 11/047,555

(22) Filed: Feb. 2, 2005

(30) Foreign Application Priority Data
Mar. 16, 2004 (TW) 93106908

(51) Int. Cl. H01L 23/48

(52) U.S. Cl. 257/738

(57) ABSTRACT

A signal transmitting device with vias and solder balls comprises: at least one main structure(s), a second substrate, a third substrate, at least one via(s), at least one conductive layer(s), at least one solder pad(s) and at least one solder ball(s). The main structure comprises at least one first substrate having a first surface and a second surface, wherein the first surface has a first circuit layer disposed thereon and the second surface has a second circuit layer disposed thereon. The second substrate is disposed on the first circuit layer and the third substrate is disposed on the second circuit layer. The via passes through the second substrate, the main structure and the third substrate sequentially. The conductive layer is disposed on the rim of the via and also the second substrate and the third substrate so that a parameter representing the width of covered area on the second substrate and the third substrate is properly equal to d. The solder pad is disposed on the second substrate and is connected to the conductive layer and, the solder ball is disposed on the solder pad. An aperture corresponding to the via is formed on the first circuit layer and the second circuit layer, and a slot is arranged corresponding to the solder ball.

### BACKGROUND OF THE INVENTION

The present invention generally relates to a signal transmitting device and, more particularly, to a signal transmitting device with a ball grid array (BGA) type package having vias and solder balls.

### FIELD OF THE INVENTION

In recent years, with the rapid development in semiconductor manufacturing technology, solid-state electronic products have been widely used and become daily necessities that people can never live without. As the request of human increases, the electronic products provide more functions and higher integration so as to achieve compactness. Since the electronic components have occupied most of the area on the circuit board, layout design concerning transmission impedance becomes more and more complicated than ever. Therefore, parasitic capacitance may result from vias and solder balls and cause impedance mismatch in signal transmission path, which adversely affects high-frequency response.

Please refer to FIG. 1A to FIG. 1D, which are schematic diagrams showing a ball grid array (BGA) type package having vias and solder balls in the prior art. As shown in FIG. 1A, the conventional BGA type package 1 having a via 16 and a solder ball 19 provides a first circuit layer 12 on a top surface of a first substrate 11 and a second circuit layer 13 on a bottom surface of the first substrate 11. The BGA type package 1 is activated by alternate current (AC) signals; therefore the first circuit layer 12 is a signal layer (a grounding layer) and the second circuit layer 13 is a grounding layer (a signal layer). In FIG. 1A, taking a 4-layer BGA type package 1 for example, a second substrate 14 is further provided on the first circuit layer 12 and a third substrate 15 is provided on the second circuit layer 13. At least one via(s) 16 is then provided passing through the second substrate 14, the first circuit layer 12, the first substrate 11, the second circuit layer 13 and the third substrate 15. A conductive layer 17 is disposed on the rim of the via 16 and also the second substrate 14 and the third substrate 15 so that a parameter representing the width of covered area on the second substrate 14 and the third substrate 15 is equal to d. Furthermore, a solder pad 18 is formed on the third substrate 15 and is connected to the conductive layer 17. Finally, a solder ball 19 is formed on the solder pad 18. More particularly, an aperture 10 is formed on the first circuit layer 12 and the second circuit layer 13, and the aperture 10 is larger than the via 16 so as to enclose the via 16.

The solder ball 19, and the second circuit layer 13 and the first circuit layer 12 are formed of metallic materials such that parasitic capacitance appears as a result of a dielectric material disposed between metallic materials. Parasitic capacitance further increases due to the downsized, thinned and more compact structure. Therefore, there is need in providing a solution in lowering the parasitic capacitance so as to overcome impedance mismatch during signal transmission.

### SUMMARY OF THE INVENTION

It is the primary object of the present invention to provide a signal transmitting device with vias and solder balls, characterized in that a clearance corresponding to one of the solder balls is extended so as to reduce the parasitic capacitance resulting from being disposed between solder balls and overcome impedance mismatch during signal transmitting.

It is another object of the present invention to provide a signal transmitting device with vias and solder balls, characterized in that a package having vias and solder balls is provided so as to ensure high-frequency response of a packaged chip.

It is still another object of the present invention to provide a signal transmitting device with vias and solder balls, ensuring impedance mismatch without any additional circuit implement.

In order to achieve the foregoing objects, the present invention provides a signal transmitting device with vias and solder balls, comprising:
at least one main structure, including at least
a first substrate with a first surface and a second surface;
a first circuit layer formed on said first surface;
a second circuit layer formed on said second surface;
a second substrate formed on said first circuit layer;
a third substrate formed on said second circuit layer;
at least one via passing through said second substrate, said main structure and said third substrate sequentially;
at least one conductive layer disposed on said rim of said via and also said second substrate and said third substrate so that a parameter representing said width of covered area on said second substrate and said third substrate is equal to d;
at least one solder pad disposed on said second substrate and is connected to said conductive layer; and
at least one solder ball disposed on said solder pad,
wherein an aperture corresponding to said via is formed on said first circuit layer and said second circuit layer, and a slot is arranged corresponding to said solder ball.

In order to achieve the foregoing objects, the present invention further provides a signal transmitting device with vias and solder balls, comprising:
a first main structure including a first substrate, on which a first circuit layer is formed on one surface and a second circuit layer is formed on the other surface;
a second main structure including a second substrate, which is coupled to said first circuit layer on one surface and is coupled to said second circuit layer on the other surface;
a third substrate formed on said second circuit layer;
a fourth substrate formed on said third circuit layer;
at least one via passing through said fourth substrate, said second main structure, said first main structure and said third substrate sequentially;
at least one conductive layer disposed on said rim of said via and also said fourth substrate and said third substrate so that a parameter representing said width of covered area on said fourth substrate and said third substrate is equal to d;
at least one solder pad disposed on said third substrate and is connected to said conductive layer; and
at least one solder ball disposed on said solder pad;
wherein an aperture corresponding to said via is formed on said first circuit layer, said second circuit layer and said third circuit layer, and a slot corresponding to said solder ball is arranged on said first circuit layer and said second circuit layer.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms.

### BRIEF DESCRIPTION OF THE DRAWINGS

The objects, spirits and advantages of the preferred embodiments of the present invention will be readily understood by the accompanying drawings and detailed descriptions, wherein:

FIG. 1A is a cross-sectional diagram showing a ball grid array (BGA) type package having vias and solder balls in the prior art;

FIG. 1B is a perspective-view diagram showing a ball grid array (BGA) type package having vias and solder balls in the prior art;

FIG. 1C is a perspective-view diagram showing vias and solder balls connected in a grid array (BGA) type package in the prior art;

FIG. 1D is a top-view diagram showing a ball grid array (BGA) type package in the prior art;

FIG. 2A is a cross-sectional diagram showing a ball grid array (BGA) type package having vias and solder balls according to a first embodiment of the present invention;

FIG. 2B is a perspective-view diagram showing a ball grid array (BGA) type package having vias and solder balls according to a first embodiment of the present invention;

FIG. 2C is a top-view diagram showing a ball grid array (BGA) type package according to a first embodiment of the present invention;

FIG. 3A is a top-view diagram showing a circuit layer according to a first embodiment of the present invention;

FIG. 3B is a top-view diagram showing a circuit layer according to a second embodiment of the present invention;

FIG. 3C is a top-view diagram showing a circuit layer according to a third embodiment of the present invention;

FIG. 3D is a top-view diagram showing a circuit layer according to a fourth embodiment of the present invention;

FIG. 4A is a cross-sectional diagram showing a ball grid array (BGA) type package having vias and solder balls according to a second embodiment of the present invention;

FIG. 4B is a cross-sectional diagram showing a ball grid array (BGA) type package having vias and solder balls according to a third embodiment of the present invention;

FIG. 5A is a graph showing the reflection loss as a function of frequency for various clearance sizes of the present invention compared with conventional parameters in the prior art;

FIG. 5B is a graph showing the insertion loss as a function of frequency for various clearance sizes of the present invention compared with conventional parameters in the prior art;

FIG. 5C is a graph showing the resistance as a function of frequency for various clearance sizes of the present invention compared with conventional parameters in the prior art;

FIG. 5D is a graph showing the reactance as a function of frequency for various clearance sizes of the present invention compared with conventional parameters in the prior art; and

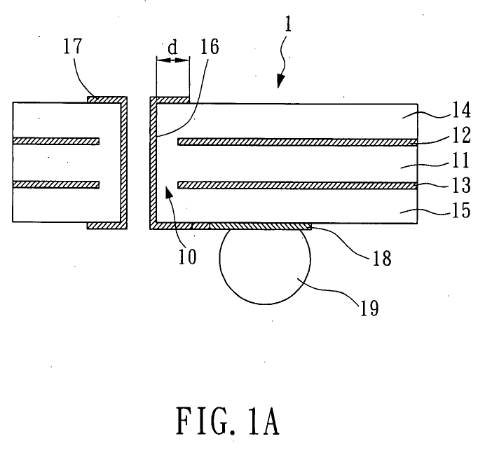

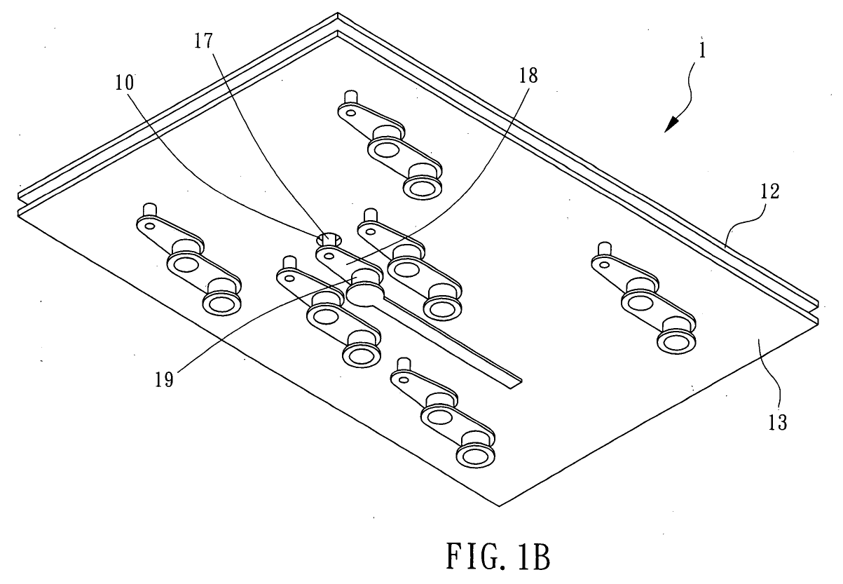

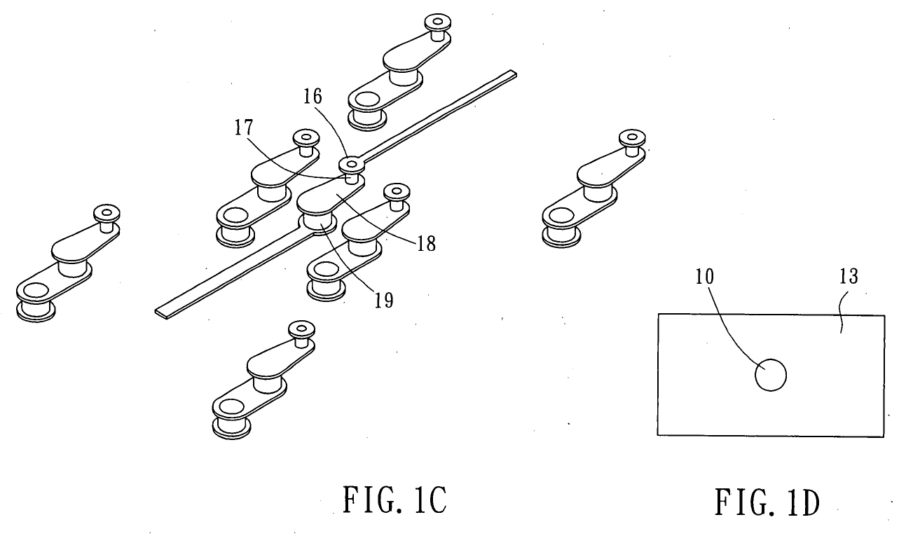

Table 1 is a table of responses of signal propagating structures at interested frequencies according to the present invention.

### DETAILED DESCRIPTION OF THE INVENTION

The present invention providing a signal transmitting device with vias and solder balls can be exemplified by the preferred embodiments as described hereinafter.

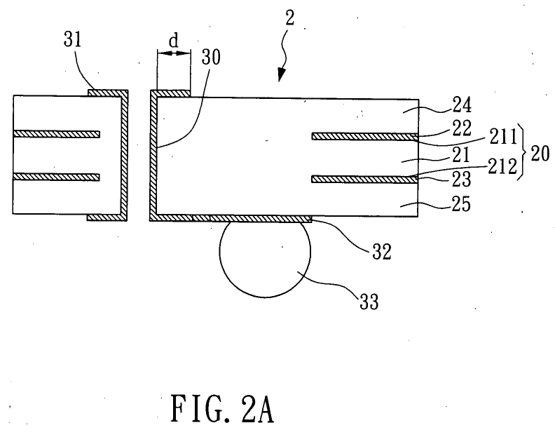

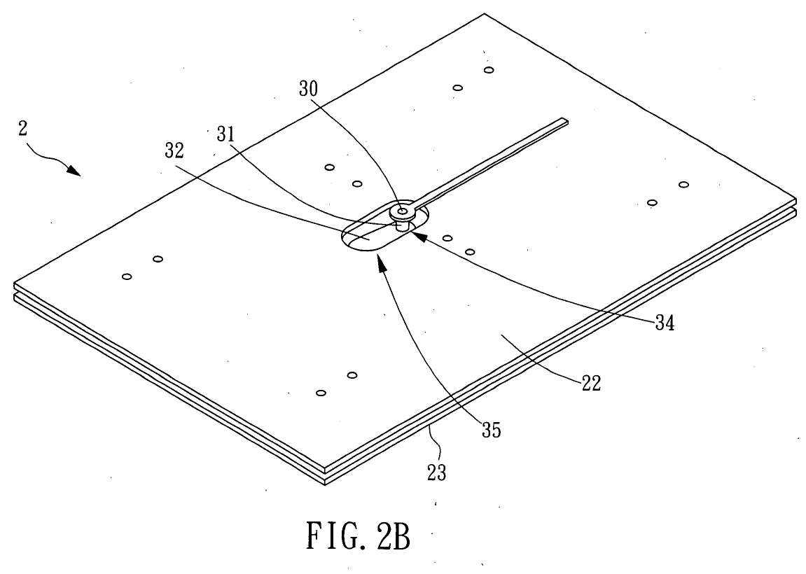

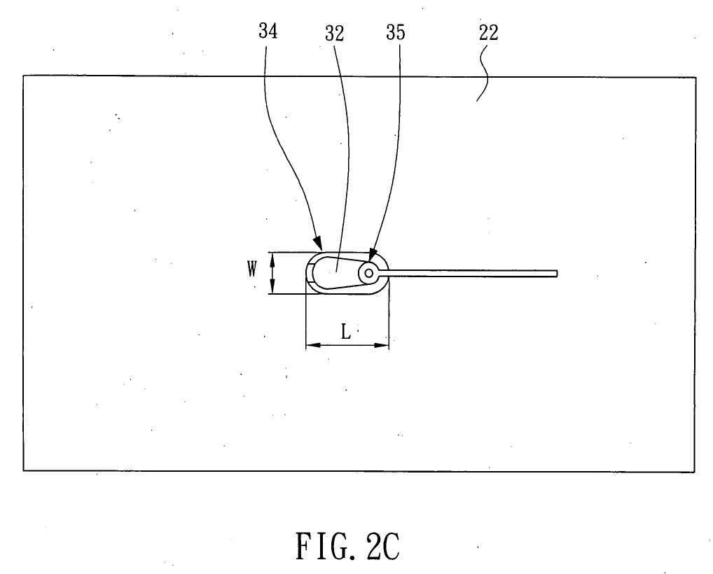

Please refer to FIG. 2A to FIG. 2C, showing a ball grid array (BGA) type package having vias and solder balls according to a first embodiment of the present invention. The signal transmitting device 2 with vias and solder balls of the present invention comprises a main structure 20, a second substrate 24, a third substrate 25, at least one via(s) 30, at least one conductive layer(s) 31, at least one solder pad(s) 32 and at least one solder ball(s) 33. The main structure 20 comprises at least one first substrate 21 with a first surface 211 and a second surface 212. The first surface 211 is covered by a first circuit layer 22 and the second surface 212 is covered by a second circuit layer 23. The first circuit layer 22 and the second circuit layer 23 are made of a conductive material. The first circuit layer 22 is used as a signal layer (or a grounding layer) and the second circuit layer 23 is a grounding layer (or a signal layer). The second substrate 24 is formed on the first circuit layer 22 and the third substrate 25 is formed on the second circuit layer 23. The first substrate 21, the second substrate 24 and the third substrate 25 are formed of an insulating material so as to electrically isolate the first circuit layer 22 and the second circuit layer 23.

The via 30 passes through the second substrate 24, the main structure 20 and the third substrate 25 so that circuits on both sides of the via 30 can be electrically coupled. The conductive layer 31 is formed on the rim of the via 30 and also the second substrate 24 and the third substrate 25 so that a parameter representing the width of covered area on the second substrate 24 and the third substrate 25 is equal to d. Furthermore, the solder pad 32 is formed on the third substrate 25 and is connected to the conductive layer 31. Finally, the solder ball 33 is formed on the solder pad 32. Since the conductive layer 31, the solder pad 32 and the solder ball 33 are formed of conductive materials, the circuit (not shown) on the second substrate 24 and the circuit (not shown) on the third substrate 25 can be electrically connected.

More particularly, an aperture 34 is formed on the first circuit layer 22 and the second circuit layer 23, and the rim of the aperture 34 is larger than the rim of the via 30 so as to enclose the via 30. A clearance is formed of a dielectric material between the rim of the aperture 34 and the rim of the via so as to reduce the parasitic capacitance resulting from being disposed between the solder balls 33. In one preferred embodiment of the present invention, corresponding to the solder ball 33, a slot 35 is further provided on the first circuit layer 22 and the second circuit layer 23, respectively. The slot 35 is in a circular form. The aperture 34 and the slot 35 are joined and form a capsule shape with a length of L and a width of W. Furthermore, the aperture 34 and the slot 35 are filled with a dielectric material. No additional manufacturing process is required because such structure is formed simultaneously when the signal transmitting device 2 is made.

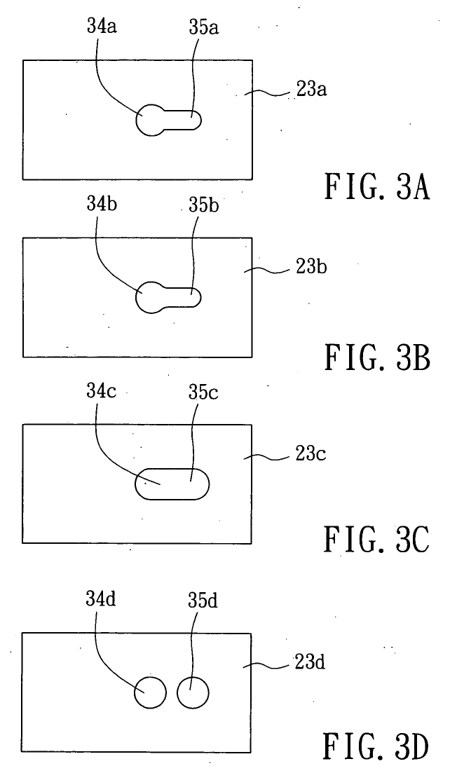

Please refer to FIG. 3A to 3D, which show a top-view diagram of a circuit layer according to four embodiments of the present invention. In these embodiments, the top view of the first circuit layer 22 is the same as that of the second circuit layer 23, and therefore only the second circuit layer 23 is shown. Also note that similar elements are given similar numbers and descriptions thereof are thus omitted.

In FIG. 3A, the aperture 34a and the slot 35a are joined, and the rim of the slot 35a is smaller than the rim of the aperture 34a, thus forming a key shape. In order to avoid point discharge at the joint between the aperture 34b and the slot 35b, the joint is smoothed as shown in FIG. 3B. In FIG. 3C, the aperture 34c and the slot 35c are joined, and the rim of the slot 35a is the same as the rim of the aperture 34a, thus forming a capsule shape. In FIG. 3D, the aperture 34a and the slot 35a are not joined, and the rim of the slot 35a can be different from (or the same as) the rim of the aperture 34a. In other words, those skilled in the art can make modifications according to the above description, and such modifications are still within the scope of the present invention.

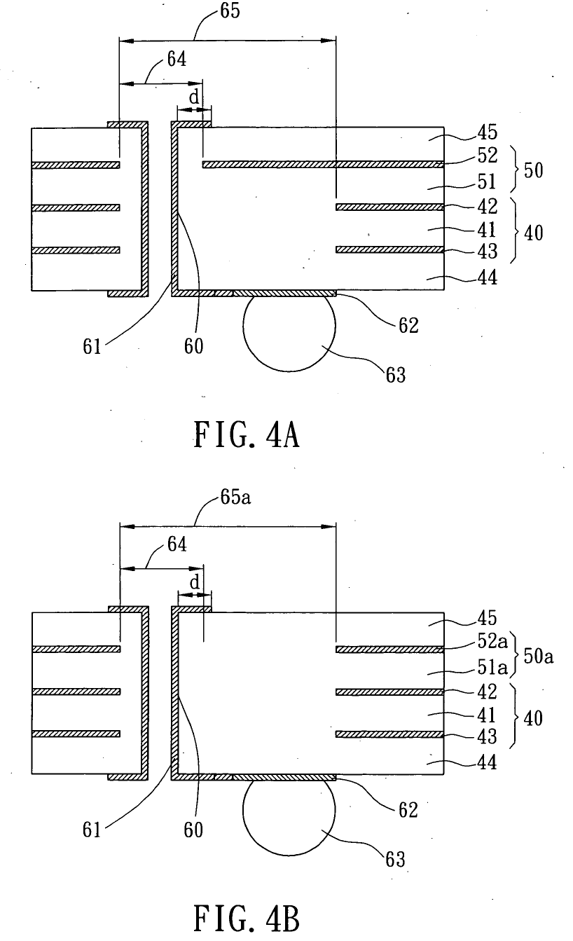

Please further refer to FIG. 4A and FIG. 4B, which show a cross-sectional diagram of a ball grid array (BGA) type package having vias and solder balls according to a second embodiment of the present invention. The signal transmitting device 4 with vias and solder balls of the present invention comprises a first main structure 40, a second main structure 50, a third substrate 44, a fourth substrate 45, at least one via(s) 60, at least one conductive layer(s) 61, at least one solder pad(s) 62 and at least one solder ball(s) 63. The first main structure 40 comprises a first substrate 41 providing a first circuit layer 42 on a top surface and a second circuit layer 43 on a bottom surface. The second main structure 50 is disposed on the first main structure 40. The second main structure 50 comprises a second substrate 51 connected to the first circuit layer 42 on a bottom surface and having a third circuit layer 52 on a bottom surface. The third substrate 44 is disposed on the third circuit layer 43. The fourth substrate 45 is formed on the third circuit layer 52. The first circuit layer 42, the second circuit layer 43 and the third circuit layer 52 are formed of a conductive material(s). The first circuit layer 42 is used as a signal layer (or a grounding layer), the second circuit layer 43 is a grounding layer (or a signal layer) and the third circuit layer 52 is a grounding layer (or a signal layer). Therefore, when manufacturing multi-layer circuit board, a common signal layer (or a grounding layer) can be used so as to reduce circuit board thickness. The via 60 passes through the fourth substrate 45, the second main structure 50, the first main structure 40 and the third substrate 44 so that the conductive layer 61 is disposed on the rim of the via 60 and a parameter representing the width of covered area on the fourth substrate 45 and the third substrate 44 is equal to d. Furthermore, the solder pad 62 is formed on the third substrate 44 and is connected to the conductive layer 61. Finally, the solder ball 63 is formed on the solder pad 62. The conductive layer 61, the solder pad 62 and the solder ball 63 are formed of conductive materials. An aperture 64 corresponding to the via 60 is provided on the first circuit layer 42, the second circuit layer 43 and the third circuit layer 52. The aperture 64 is in a circular form and the rim of the aperture 64 is larger than the rim of the via 60. Between the rim of the aperture 64 and the rim of the via 60 is filled with a dielectric material. In the preferred embodiment of the present invention, a slot 65 corresponding to the solder ball 63 is formed only on the first circuit layer 42 and the second circuit layer 43 because the third circuit layer 52 has less contribution to the parasitic capacitance between the solder balls 63. Certainly, smaller parasitic capacitance can be achieved if a slot 65a is formed on the first circuit layer 42, the second circuit layer 43 and the third circuit layer 52a. However, such modification is within the scope of the invention and can be made by persons with ordinary skills in this art and thus description thereof can be omitted.

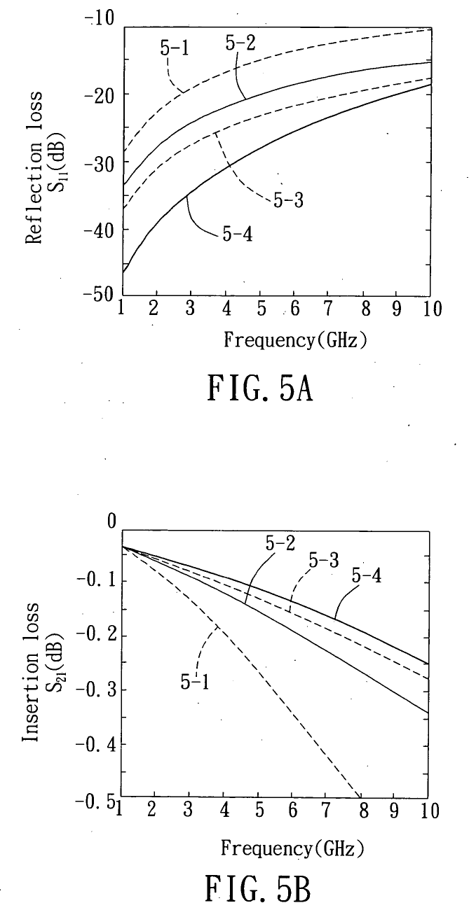

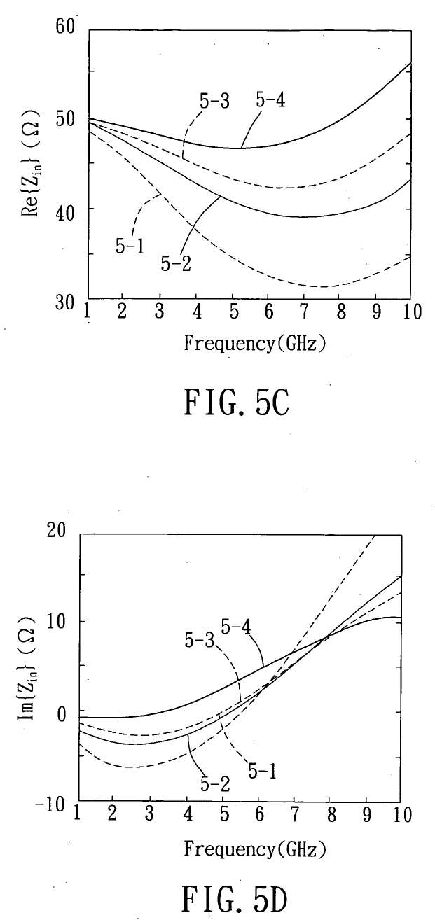

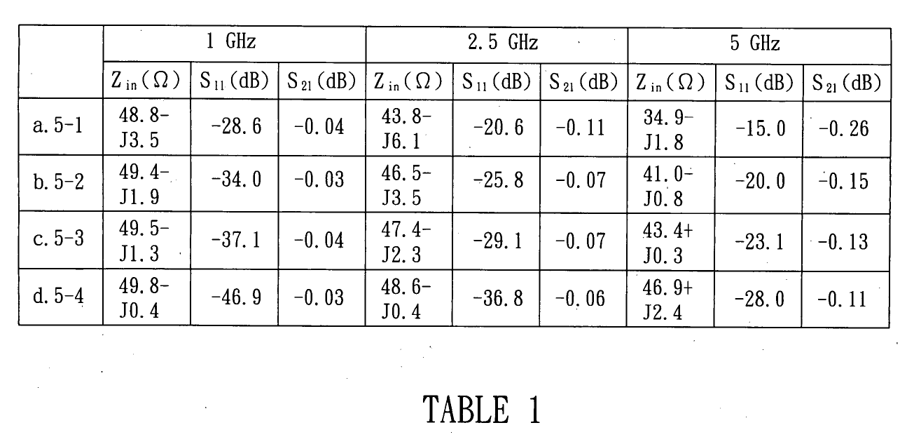

Please refer to FIG. 5A to FIG. 5D and Table 1, which show graphs of the reflection loss, the insertion loss, the resistance and the reactance as a function of frequency and a comparison table representing responses of signal propagating structures at interested frequencies according to the present invention. The response of the conventional propagating structure is denoted as 5-1, in which the real part of the impedance (resistance) is kept larger than 40 ohms when the frequency is below 2.5 GHz and the real part of the impedance (resistance) is about 35 ohms when the frequency is at 5 GHz. The return loss is reduced to less than 15 dB up to 2.5 GHz. Since the input impedance is obviously lower than 50 ohms before 5 GHz, it can be concluded that the solder ball has induced a larger capacitance and hence lower the impedance of the signal path. Therefore, reducing the capacitance induced by the solder ball is a direct method to improve the impedance matching of the signal path. In the figures, however, lines 5-2, 5-3 and 5-4 denote the signal propagating structures with the compensated clearance. Three different sizes of the extended clearances were considered. The clearance has a width of 0.68 mm (L=0.68 mm) and a length of 1.295 mm (W=1.295 mm) for 5-2, L=0.8 mm and W=1.415 mm for 5-3 and L=11.0 mm and W=1.615 mm for 5-4, respectively. The responses of these structures are also shown in FIG. 5A to FIG. 5D and Table 1 for comparison. The results show that impedance matching is improved significantly as the clearance becomes larger. In other words, the real part of the input impedance of the signal propagating structure 5-4 is larger than 45 ohms and closer to the system impedance when the frequency is up to 5 GHz. Its return loss approaches to 30 dB even at 5 GHz. Since the return loss is improved, the insertion loss of the tuned structure is surely decreased. Moreover, not only the real part of the input impedance is compensated, but the imaginary part is also reduced. Therefore, the input impedance of the tuned structure approaches to the system impedance much more. In addition to the improvement of the performance, this compensation method also has the advantage of keeping the circuit size. Since no additional circuit implement is required, this signal propagating structure could be kept simple and its size would not increase.

According to the above discussion, the present invention discloses a signal transmitting device with vias and solder balls so as to reduce the parasitic capacitance resulting from being disposed between solder balls and overcome impedance mismatch during signal transmitting. Therefore, the present invention has been examined to be new, non-obvious and useful.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

1. A signal transmitting device with vias and solder balls, comprising:
at least one main structure, including at least
a first substrate with a first surface and a second surface;
a first circuit layer formed on said first surface;
a second circuit layer formed on said second surface;
a second substrate formed on said first circuit layer;
a third substrate formed on said second circuit layer;
at least one via passing through said second substrate, said main structure and said third substrate sequentially;
at least one conductive layer disposed on said rim of said via and also said second substrate and said third substrate so that a parameter representing said width of covered area on said second substrate and said third substrate is equal to d;
at least one solder pad disposed on said second substrate and is connected to said conductive layer; and
at least one solder ball disposed on said solder pad;
wherein an aperture corresponding to said via is formed on said first circuit layer and said second circuit layer, and a slot is arranged corresponding to said solder ball.

2. The signal transmitting device with vias and solder balls as recited in claim 1, wherein the rim of said aperture is larger than the rim of said via.

3. The signal transmitting device with vias and solder balls as recited in claim 1, wherein said aperture is in a circular form.

4. The signal transmitting device with vias and solder balls as recited in claim 1, wherein said slot is in a circular form.

5. The signal transmitting device with vias and solder balls as recited in claim 1, wherein said aperture and said slot are joined.

6. The signal transmitting device with vias and solder balls as recited in claim 1, wherein said aperture and said slot form a key shape.

7. The signal transmitting device with vias and solder balls as recited in claim 1, wherein said aperture and said slot form a capsule shape.

8. The signal transmitting device with vias and solder balls as recited in claim 1, wherein said first substrate, said second substrate and said third substrate are formed of an insulating material.

9. The signal transmitting device with vias and solder balls as recited in claim 1, wherein said aperture and said slot are filled with an insulating material.

10. The signal transmitting device with vias and solder balls as recited in claim 1, wherein said first circuit layer and said second circuit layer are made of a conductive material.

11. A signal transmitting device with vias and solder balls, comprising:
a first main structure including a first substrate, on which a first circuit layer is formed on one surface and a second circuit layer is formed on the other surface;
a second main structure including a second substrate, which is coupled to said first circuit layer on one surface and is coupled to said second circuit layer on the other surface;
a third substrate formed on said second circuit layer;
a fourth substrate formed on said third circuit layer;
at least one via passing through said fourth substrate, said second main structure, said first main structure and said third substrate sequentially;
at least one conductive layer disposed on said rim of said via and also said fourth substrate and said third substrate so that a parameter representing said width of covered area on said fourth substrate and said third substrate is equal to d;
at least one solder pad disposed on said third substrate and is connected to said conductive layer; and
at least one solder ball disposed on said solder pad;
wherein an aperture corresponding to said via is formed on said first circuit layer, said second circuit layer and said third circuit layer, and a slot corresponding to said solder ball is arranged on said first circuit layer and said second circuit layer.

12. The signal transmitting device with vias and solder balls as recited in claim 11, wherein said aperture and said slot are joined.

13. The signal transmitting device with vias and solder balls as recited in claim 11, wherein said aperture and said slot form a key shape.

14. The signal transmitting device with vias and solder balls as recited in claim 11, wherein said aperture and said slot form a capsule shape.

15. The signal transmitting device with vias and solder balls as recited in claim 11, wherein said aperture and said slot are filled with an insulating material.

16. The signal transmitting device with vias and solder balls as recited in claim 11, wherein a slot corresponding to said solder ball is further provided on said third circuit layer.

17. The signal transmitting device with vias and solder balls as recited in claim 11, wherein the rim of said aperture is larger than the rim of said via.

18. The signal transmitting device with vias and solder balls as recited in claim 11, wherein said aperture is in a circular form.

19. The signal transmitting device with vias and solder balls as recited in claim 11, wherein said first substrate, said second substrate, said third substrate and said fourth substrate are formed of an insulating material.

20. The signal transmitting device with vias and solder balls as recited in claim 11, wherein said slot is in a circular form.

21. The signal transmitting device with vias and solder balls as recited in claim 11, wherein said first circuit layer, said second circuit layer and said third circuit layer are made of a conductive material.

22. The signal transmitting device with vias and solder balls as recited in claim 16, wherein said aperture and said slot are joined.

23. The signal transmitting device with vias and solder balls as recited in claim 16, wherein said aperture and said slot form a key shape.

24. The signal transmitting device with vias and solder balls as recited in claim 16, wherein said aperture and said slot form a capsule shape.

25. The signal transmitting device with vias and solder balls as recited in claim 16, wherein said aperture and said slot are filled with an insulating material.

26. A signal transmitting device, comprising:
a substrate with a plurality of conductive layers thereon;
a signal cable for connecting a first conductive layer to a second conductive layer through a via;
a grounding plane disposed between said first conductive layer and said second conductive layer; and
at least one solder ball coupled to said corresponding signal cable on said second circuit layer so as to connect the signal to external circuitry;
wherein said grounding plane forms an insulating opening by keeping distant from said via and further forms an aperture by shrinking towards said solder ball so as to reduce parasitic capacitance induced by said solder ball.

27. The signal transmitting device as recited in claim 22, wherein said aperture is slightly smaller than said insulating opening.

28. The signal transmitting device as recited in claim 22, wherein said aperture is equal to said insulating opening.
